(19) United States
(12) Patent Application Publication
(10) Pub. No.: US 2014/0373916 A1
(43) Pub. Date: Dec. 25, 2014

(54) PHOTOVOLTAIC DEVICE AND METHOD OF MANUFACTURE

(71) Applicants: Hany AZIZ, Oakville (CA); Yichun LUO, Oakville (CA); Qi WANG, Waterloo (CA)

(72) Inventors: Hany Aziz, Oakville (CA); Yichun Luo, Oakville (CA); Qi Wang, Waterloo (CA)

(21) Appl. No.: 14/374,620

(22) PCT Filed: Jan. 28, 2013
(86) PCT No.: PCT/CA2013/050057

§ 371 Date: Jul. 25, 2014

Related U.S. Application Data
(60) Provisional application No. 61/632,622, filed on Jan. 27, 2012.

(51) Int. Cl. H01L 51/42; H01L 51/44

(52) U.S. Cl. CPC H01L 51/424; H01L 51/441
USPC 136/256; 136/263; 438/82

(57) ABSTRACT

The disclosure is directed at a photovoltaic device for converting solar power into electric power, the photovoltaic device including a first electrode; a second electrode; an organic photoactive region in between the first electrode and the second electrode; and an interface stabilizing region in between the organic photoactive region and one of the first electrode or the second electrode; wherein the interface stabilizing region is selected from at least one of a non-conjugated organic material, a non-conjugated metalloorganic compound, and a non-alkali metal halide inorganic metal compound.

### CROSS REFERENCE TO RELATED APPLICATIONS

This application claims the benefit of priority of U.S. Provisional Patent Application No. 61/632,622 filed Jan. 27, 2012, which is incorporated herein by reference in its entirety.

### FIELD

The present disclosure relates generally to photovoltaic devices for converting light into electrical power. More particularly, the present disclosure relates to a photovoltaic device and a method of manufacturing a photovoltaic device.

### BACKGROUND

Limited device stability is a factor that hinders the wide success and commercialization of organic solar cells (OSCs). Gradual changes in the materials cause the power conversion efficiency of an OSC to decrease with time, thus limiting its useful (i.e., service) life. Conventionally, approaches for improving OSC stability have focused on addressing degradation issues caused by ambient moisture and oxygen, which affects both the bulk active layer as well as the organic electrode interface. Exposure to light, such as sunlight, also causes changes in the solar cell that reduce its solar cell. This behavior is referred to as poor photo-stability and occurs even in inert environments.

The poor photo stability is caused by changes at the photoactive organic layer/electrode interfaces that happen under illumination and occur in organic optoelectronic devices in general, including organic light emitting devices (OLEDs), organic photodetectors (OPDs) and OSCs.

It is, therefore, desirable to provide a photovoltaic device with improved photo-stability.

### SUMMARY

The limited photo-stability of OSCs is one of the main challenges hindering the commercialization of this new technology. This disclosure addresses the issue and provides means for increasing stability via at least one interface stabilization layer.

Poor photo-stability of OSCs may originate from the poor photo-stability of the metal contact and its interface with the active region. Using a thin interface stabilization layer (e.g. of approximately 1 nm) comprising a photo-stable material, such as lithium acetylacetonate (Li(acac)), at the metal electrode contact, increases OSC stability.

Key features or characteristics include using a thin interface stabilization layer at the metal contact in an OSC, using a thin interface stabilization layer comprising Li(acac) or Cs (CO3)2 at the metal contact in an OSC, and the use of thermal deposition in vacuum or solution coating technique for fabricating the interface stabilization layer in an OSC.

Key distinctive benefits of this technology include increased functionality, low cost as solution processing can be used in device fabrication, and devices can be flexible when it applied on flexible substrate. It is an object of the present disclosure to obviate or mitigate at least one disadvantage of previous systems.

In a first aspect, the present disclosure provides a photovoltaic device for converting solar power into electric power, the photovoltaic device comprising a first electrode; a second electrode; an organic photoactive region in between the first electrode and the second electrode; and an interface stabilizing region in between the organic photoactive region and one of the first electrode and the second electrode; wherein the interface stabilizing region is selected from at least one of a non-conjugated organic material, a non-conjugated metalloorganic compound, and a non-alkali metal halide inorganic metal compound.

In a further embodiment, there is provided a method of manufacturing a photovoltaic device, the method comprising obtaining a bottom electrode; obtaining a top electrode; depositing an organic photoactive region above the bottom electrode and below the top electrode; and depositing an interface stabilizing region between the organic photoactive region and one of the bottom electrode and the top electrode; wherein the interface stabilizing region is selected from at least one of a non-conjugated organic material, a non-conjugated metalloorganic compound, and a non-alkali metal halide inorganic metal compound.

Other aspects and features of the present disclosure will become apparent to those ordinarily skilled in the art upon review of the following description of specific embodiments in conjunction with the accompanying figures.

### BRIEF DESCRIPTION OF THE DRAWINGS

Embodiments of the present disclosure will now be described, by way of example only, with reference to the attached Figures.

FIG. 1 is a schematic diagram of a photovoltaic device, in accordance with a first embodiment;

FIG. 2 is a schematic diagram of a photovoltaic device, in accordance with a second embodiment;

FIG. 3 is a schematic diagram of a photovoltaic device, in accordance with a third embodiment;

FIGS. 4A, 4B, and 4C are schematic diagrams of photovoltaic devices with an electron extraction layer, in accordance with further embodiments;

FIGS. 5A, 5B, and 5C are schematic diagrams of photovoltaic devices with a hole extraction layer, in accordance with alternative embodiments;

FIG. 6 are graphs of photovoltaic device efficiency; and

FIG. 7 is a flow chart of a method of manufacturing a photovoltaic device, in accordance with an embodiment.

### DETAILED DESCRIPTION

Generally, the present disclosure provides for a photovoltaic device having an interface stabilization layer and methods of manufacture. In one embodiment, the interface stabilization layer assists to provide improved photo-stability. In a particular embodiment, the present disclosure provides an organic solar cell and a method for manufacturing an organic solar cell having high stability, more specifically high photo-stability or an increased functional service life or both.

The embodiments of this disclosure can be utilized in any and all organic solar cells such as those comprising an organic photoactive material and including those comprising small molecule-based materials; polymer-based materials, and/or combinations of them, either alone or in combination with other organic or inorganic photoactive semiconductors in the active layer, when higher performance, more specifically higher stability are desired.

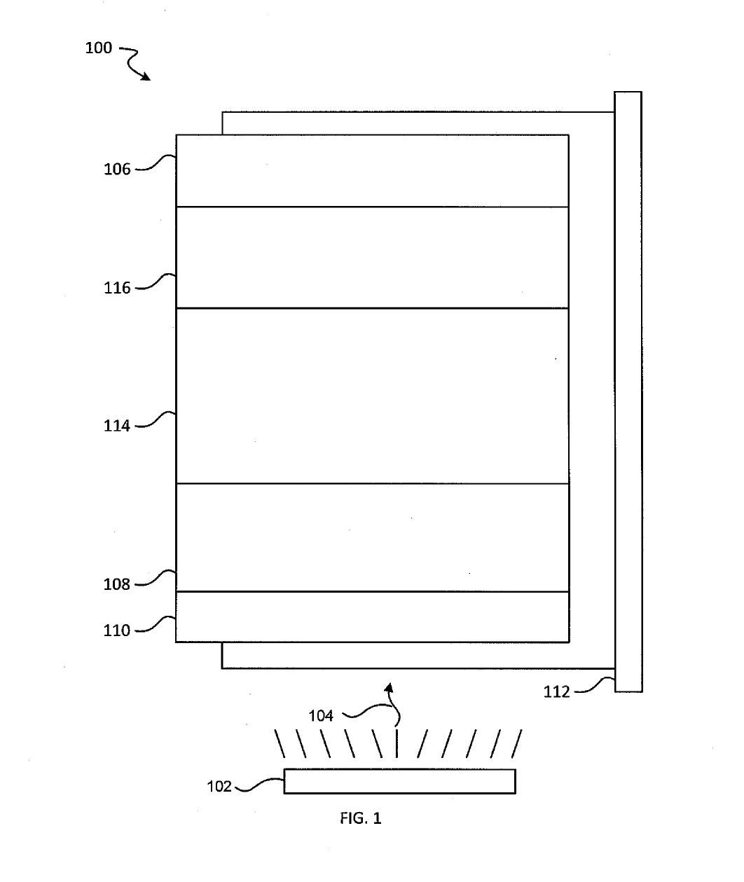

Turning to FIG. 1, a schematic diagram of a photovoltaic device 100, in accordance with a first embodiment is provided. The photovoltaic device 100 is subject to light (or solar radiation) from a source 102, such as a light source, in the direction of arrow 104. In a variant where the photovoltaic device 100 may be an inverted photovoltaic device, the photovoltaic device 100 is subject to light in a direction opposite of arrow 104 (or, in other words, from the top of the figure).

The photovoltaic device 100 includes a first, which in the embodiment of FIG. 1 may be seen as a top, reflective electrode 106 (e.g. a cathode) and a second, which in the embodiment of FIG. 1 may be seen as a bottom, transparent electrode 108 (e.g. an anode). At least one of the first electrode 106 or the second electrode 108 includes a metal layer (such as, but not limited to, aluminum (Al), magnesium (Mg), silver (Ag), calcium (Ca), Indium (In), barium (Ba),strontium (Sr), gold (Au), molybdenum (Mo), chromium (Cr) or Lithium (Li)). The bottom electrode 108 is deposited on a substrate layer 110, which may be any one of a flexible substrate layer, a plastic layer, a steel layer, or a glass layer. The electrodes 106 and 108 are operatively connected to an electric current/voltage receiving device 112 to use or store electricity which is generated by the photovoltaic device 100.

The photovoltaic device 100 further comprises an organic photoactive region 114 or layer which is deposited, or located, above the bottom electrode 108. The organic photoactive region 114 may comprise one or more layers whereby one of these layers is made from an organic photoactive material. Examples of photoactive materials that can be used in the photoactive region include oligothiophenes, polythiophenes, polypyrrole, diketopyrrolopyrroles, phthalocyanines, fullerenes, perylenes, amines, acenes, and their derivatives. In a preferred embodiment, the organic photoactive region 114 may include a blend of two materials where one of the said two materials can act as an electron donor, and the other of the said two materials can act as an electron acceptor, such as, for example, a blend of poly (3-hexylthiophene) (P3HT) and [6,6]-phenyl-C61-butyric acid methyl ester (PCBM).

At least one interface stabilizing (interfacial) layer 116 or region is also located between the two electrodes 106 and 108, and in the current embodiment is located between the photoactive region 114 and the top electrode 106. The interface stabilizing layer 116 comprises a different material from the photoactive region. In one embodiment, the interface stabilizing layer 116 may be about 0.1 nm to about 10 nm in thickness but is typically about 0.5 nm to about 5 nm in thickness.

In a preferred embodiment, the interface stabilizing layer 116 is located in between the electrode 106 or 108 which includes the metal layer (as disclosed in paragraph 22 above) and the photoactive region 114. However, the interface stabilizing layer 116 may be also located between the photoactive region 114 and the other electrode without the metal layer. In the embodiment of FIG. 1, it is assumed that the top electrode 106 includes the metal layer. The interface stabilizing layer 116 is a wide band gap material and includes a photo-stable material selected from any one or more of a non-conjugated organic compound, (such as for example a hydrocarbon or an organic compound comprising fluorine), non-conjugated metalloorganic compound (e.g. a metal acetylacetonate such as lithium acetylacetonate (Li(acac)), barium acetylacetonate (Ba(acac)), sodium acetylacetonate (Na(acac)), calcium acetylacetonate (Ca(acac)) or aluminum acetylacetonate (Al(acac))), an inorganic metal compound such as, for example, a metal oxide (e.g. molybdenum trioxide (MoO₃), aluminum oxide (Al₂O₃), magnesium oxide (MgO), silver oxide (Ag₂O)), and a metal carbonate (e.g. cesium carbonate (Cs₂CO₃), lithium carbonate Li₂CO₃, calcium carbonate (CaCO₃)). In an embodiment, alkali metal compounds are limited to ones with high photo-stability (e.g. Cs₂CO₃) which does not include alkali metal compounds that have poor photo-stability such as alkali metal halides (e.g. lithium fluoride (LiF), and caesium fluoride (CsF)).

In this disclosure, non-conjugated compounds are defined as compounds where the majority of carbon-carbon bonds (that is bonds connecting between a carbon atom and another carbon atom in the compound, as opposed to a carbon atom and a non-carbon atom. Pease reword if needed) are single bonds. In a particular embodiment, the percentage of single carbon bonds in the non-conjugated compound is more than 50%. In a further preferred embodiment, the percentage of single carbon bonds in the non-conjugated compound is 70% or more. In certain embodiments, it may be preferred if the percentage of single carbon bonds in the non-conjugated compound is 80% or more.

The interface stabilizing layer 116 decreases the number or prevents excitons from reaching the metal electrode such as the top electrode 106 in this embodiment. In operation, when the photovoltaic device 100 is exposed to solar radiation from the source 102, absorption of solar radiation by materials in the photoactive region 114 leads to the formation of excitons that are then dissociated into holes and electrons. The holes and electrons are then transported in opposite directions across the photoactive region 114 towards the two electrodes 106 and 108 rendering one of the first 106 or second electrodes 108 as a hole-collecting electrode and the other as an electron-collecting electrode.

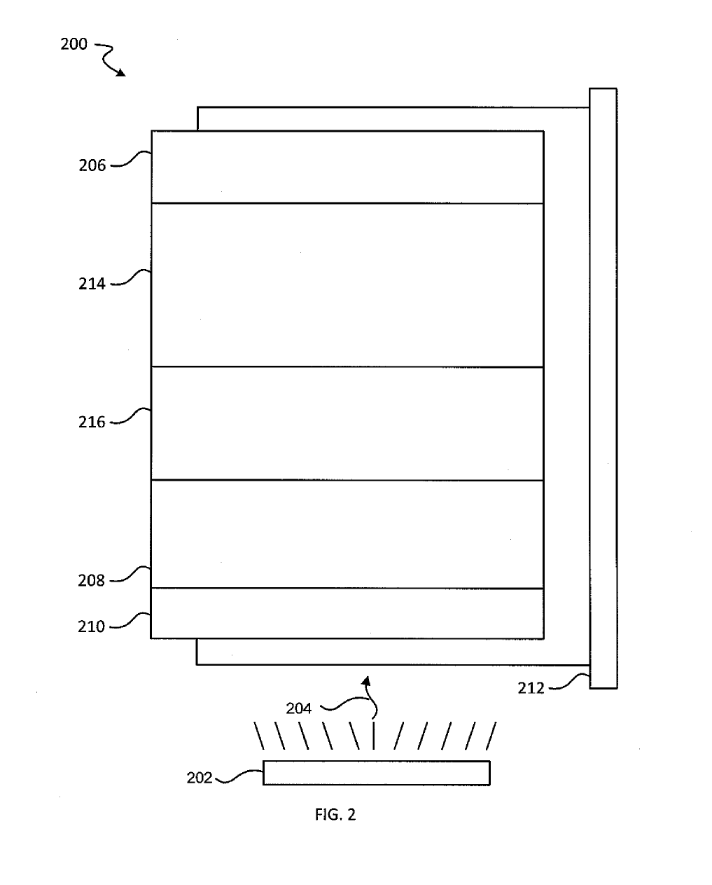

Turning to FIG. 2, a photovoltaic device 200 in accordance with a second embodiment is schematically shown. The photovoltaic device 200 has an interface stabilizing layer 216 located between a bottom electrode 208 and a photoactive region 214. As with the photovoltaic device 100, the interface stabilizing layer 216 allows for an increase in photostability of the photovoltaic device 200. The bottom electrode 208 and a top electrode 206 are operatively connected to an electricity receiving device 212.

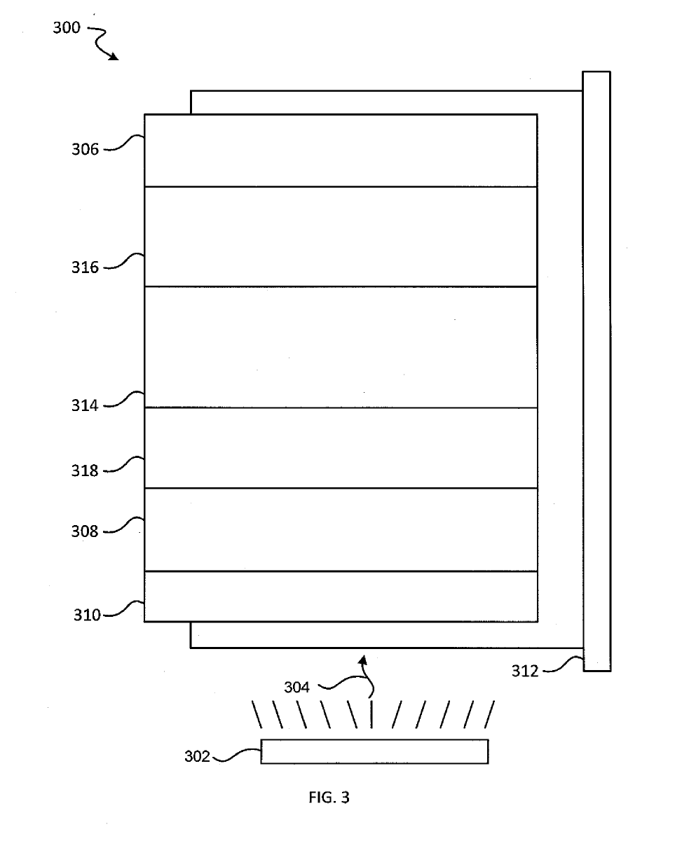

Turning to FIG. 3, a photovoltaic device 300 in accordance with a third embodiment is schematically shown. The photovoltaic device 300 is similar to that of photovoltaic device 100 except the photovoltaic device 300 includes a further interface stabilizing layer 318 between a bottom electrode 308 and a photoactive region 314. The interface stabilizing layer 318 may be seen as a second interface stabilizing layer while the interface stabilizing layer 316 may be seen as a first stabilizing layer. As with the first interface stabilizing layer 316, the second interface stabilizing layer 318 allows for a further increase in photostability of the photovoltaic device 300.

The bottom electrode 308 and a top electrode 306 are operatively connected to an electricity receiving device 312.

The second interface stabilizing layer 318 may comprise a photo-stable material selected from any one or more of a non-conjugated organic compound, a non-conjugated metalloorganic compound (e.g. a metal acetylacetonate like Li(acac), Ba(acac), Na(acac), Ca(acac) and Al(acac)), an inorganic metal compound such as, for example, a metal oxide (e.g. MoO₃, Al₂O₃), and a metal carbonate (e.g. Cs₂CO₃, Li₂CO₃).

The photoactive layer 314 may include a blend of poly (3-hexylthiophene) (P3HT) and [6,6]-phenyl-C61-butyric acid methyl ester (PCBM) active layer.

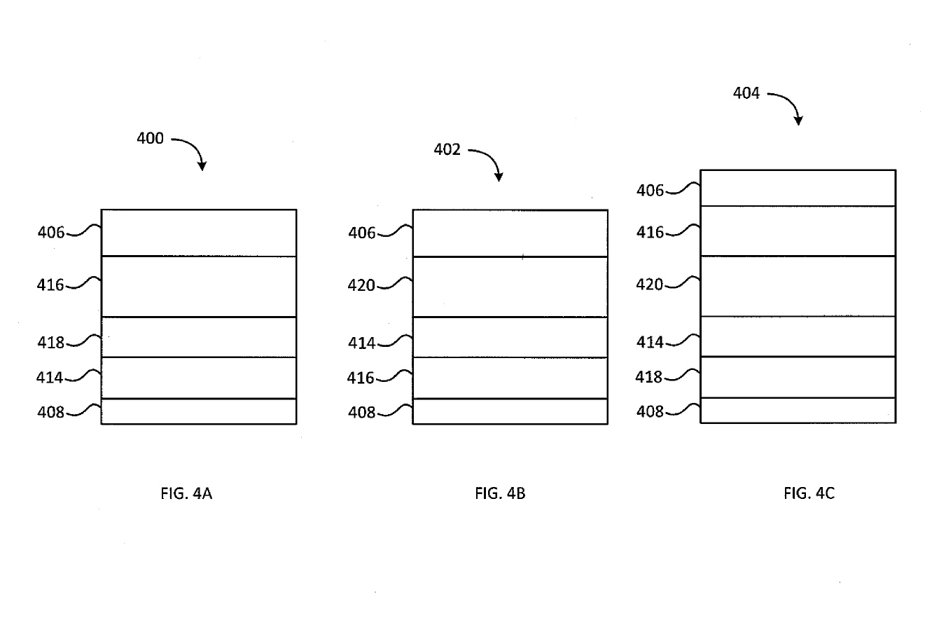

Turning to FIGS. 4A, 4B, and 4C, photovoltaic devices 400, 402, 404, (respectively) in accordance with a further embodiment are shown. The photovoltaic devices 400, 402, 404, include an electron extraction layer (EEL) 420.

In photovoltaic device 400, the EEL 420 is located below a first electrode 406 (e.g. a cathode) and an interface stabilizing layer 416, and above a photoactive region 414 and a second electrode 408 (e.g. an anode).

In photovoltaic device 402, the EEL 420 is located below the first electrode 406 (e.g. a cathode) and above the photoactive region 414, the interface stabilizing layer 416, and the second electrode 408 (e.g. an anode).

In photovoltaic device 404, the EEL 420 is located below the first electrode 406 (e.g. a cathode) and a first interface stabilizing layer 416, and above the photoactive region 414, a second interface stabilization layer 418, and the second electrode 408 (e.g. an anode).

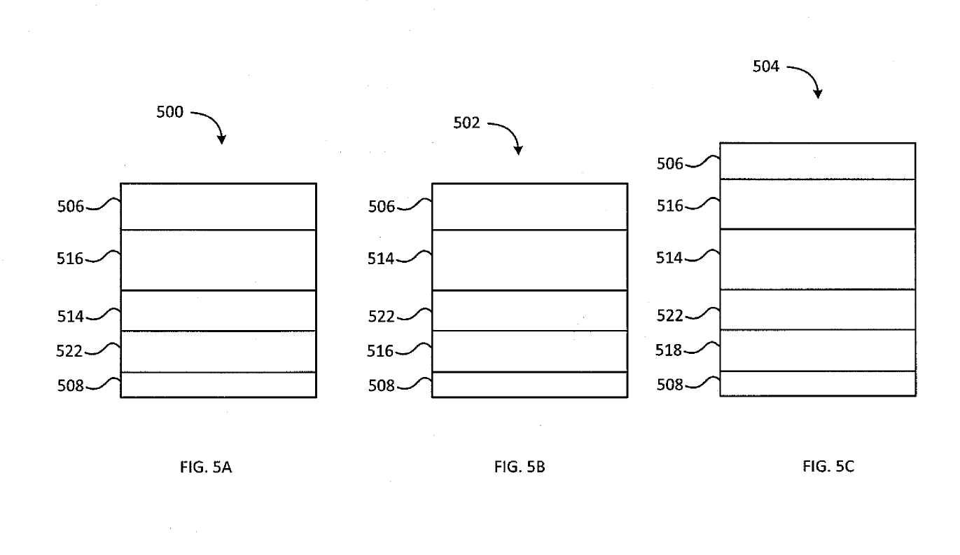

Turning to FIGS. 5A, 5B, and 5C, photovoltaic devices 500, 502, 504, (respectively) in accordance with a further embodiment are shown. The photovoltaic devices 500, 502, 504, include a hole extraction layer (HEL) 522.

In photovoltaic device 500, the HEL 522 is located below a first electrode 506 (e.g. a cathode), an interface stabilizing layer 516, and a photoactive region 514 and above a second electrode 508 (e.g. an anode).

In photovoltaic device 502, the HEL 522 is located below the first electrode 506 (e.g. a cathode) and the photoactive region 514 and above the interface stabilizing layer 516, and the second electrode 508 (e.g. an anode).

In photovoltaic device 504, the HEL 522 is located below the first electrode 506 (e.g. a cathode), a first interface stabilizing layer 516, and the photoactive region 514, and above a second interface stabilization layer 518 and the second electrode 508 (e.g. an anode).

In the embodiments of FIGS. 4A, 4B, 4C, 5A, 5B, and 5C, a substrate layer (not shown) may be adjacent to the first electrode 406, 506 or the second electrode 408, 508.

In an embodiment, electrode 408, 508 is an indium tin oxide (ITO) electrode and electrode 406, 506 is a metal electrode, such as for example, aluminum, for hole and electron collection respectively. In operation, the interface stabilizing layers, or interfacial layers 416, 516, 418, 518 facilitate the extraction of the photo generated charge carriers (holes and electrons) from the photoactive region 414 514 to the corresponding hole- and electron-selective electrodes. HEL and EEL materials include, but are not limited to, poly (3,4-ethylenedioxythiophene) poly(styrenesulfonate) (PEDOT:PSS) and MoO₃ for HELs, and LiF, Cs₂CO₃, TiOx (e.g. titanium dioxide), and zinc oxide (ZnO) for EELs whereby the latter two materials may be used in inverted solar cells where the top electrode serves as the hole-extracting electrode.

In a further embodiment, the photovoltaic device may comprise both the EEL and the HEL layers.

Turning back to FIG. 1, when the photovoltaic device is an organic solar cell (OSC), exposure of OSCs to light results in degradation in OSC parameters, even in inert environments. The use of the interface stabilizing layer 116 between the photoactive organic layer 114 and the aluminum (Al) electrode 106 suppresses contact photo-degradation and enhances OSC photo-stability. As will be understood, the discussion with respect to the parts of FIG. 1 also hold with respect to the similar numbered parts in FIGS. 2 to 5.

The interface stabilizing layer 116 between the organic photoactive region 114 and the electrodes 106 and 108 in OSCs may be based on their light, heat, and electrical stability in an inert atmosphere. As the organic/metal interface (the interface if there were no stabilizing layers present) may be inherently photo-unstable, resulting in significant losses in device efficiency with irradiation. The interface stabilizing layer 116 may reduce photo-degradation of the active layer/electrode interface. In spite of their photo-stability, certain materials used for an interfacial layer at the active layer/cathode interface cause thermal degradation due to temperature increases under exposure to light.

In the preferred embodiment, the interface stabilizing layer 116 is Li(acac). Li(acac) provides enhancements in device stability when compared to LiF EEL. In known photovoltaic devices, the interface between the photoactive region and the metal electrode is inherently photo-unstable and limits photo-stability. The use of EELs can substantially enhance photo-stability, but may reduce the thermal stability. Further, MoO₃ HELs slightly bolster the device stability. Electrical aging effects may be minor when compared to other degradation mechanisms. Li(acac) provides efficiency improvement on par with LiF, but with additional stability improvement.

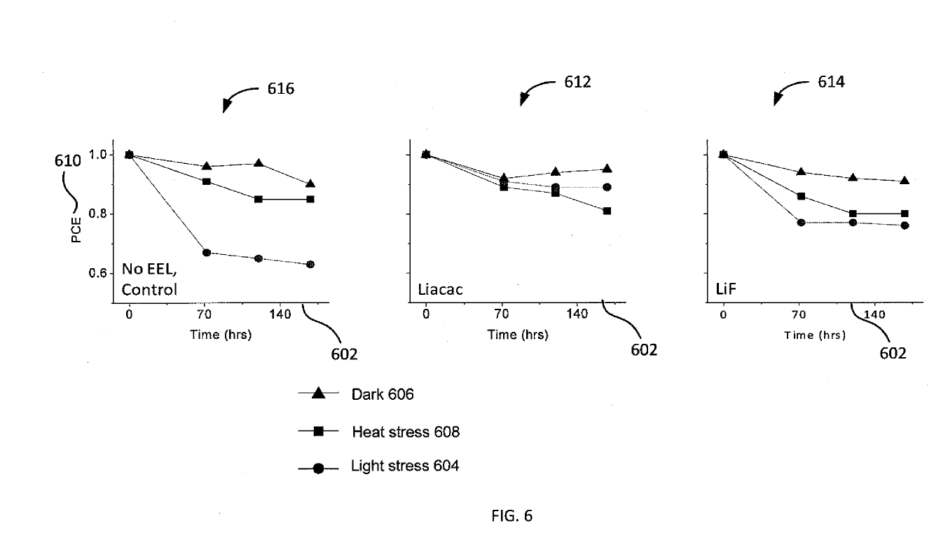

Turning to FIG. 6, results of photo-stability tests 600 on P3HT: PCBM OSCs with PEDOT: PSS HELs with a Li(acac) interface stabilizing layer 612, with a LiF interface stabilizing layer 614, and without an interface stabilizing layer 616 are shown. The OSCs were irradiated continuously by white light (100 mW/cm²) over a period of 168 hours in a nitrogen gas (N₂) atmosphere to produce a light stressed group 604. For comparison, a dark group 606 of samples, made of the same materials and structures, was kept in the dark (in a N₂ atmosphere) for the same period of time. The dark group 606 was used to test for aging effects that may occur in the devices with time regardless of the irradiation. Furthermore, in order to distinguish between photo-induced changes and any changes that may be caused by thermal stresses arising from the exposure to light, a heat stressed group 608 of samples was kept in N₂ in the dark, but heated to a temperature of 40 C, which is a few degrees above the measured temperature of the photo irradiated samples (the light stressed group 604). This allowed for thermal effects to be slightly more pronounced in the data set from the heat stressed group 608 versus that in the light stressed group 604.

In order to monitor changes in the performance as a result of the light stress, the photovoltaic characteristics of the OSCs were measured at fixed time intervals 602 during this period. All solar cells were fabricated in triplicate: the light stressed group 604 of samples for exposure to light stress, the dark group 606 of samples to be kept in the dark, and a heat stressed group 608 of samples for exposing to thermal stress. Power conversion efficiency (PCE) 610 was measured at approximately 2% for devices with a Li(acac) interface stabilizing layer 612, 2% for devices with a LiF interface stabilizing layer 614, 1% for the device without an interface stabilizing layer 616. The PCE graph 610 showed improvement by inclusion of the Li(acac) interface stabilizing layer 612 which was due to an increase in all relevant solar cell parameters, including fill factor (FF), open circuit voltage (Voc), and short circuit current (Jsc).

The normalized PCE 610 values for these devices over the 168-h aging scheme are shown in FIG. 6, normalized to the original values to facilitate cross-comparisons.

As shown in FIG. 6, the light stress leads to degradation in the performance of all devices, and the effect is pronounced in the devices without the interface stabilizing layer 616, which exhibit a decrease in PCE to 60% of their initial values after exposure to light for 168 h. This degradation is not substantially due to thermal effects, as devices exposed to heat stress alone 608 (i.e., without the light) displayed a decrease in their PCE 610 to only 85% of their initial value over the same period of time, despite the slightly higher temperature of the heat-stressed devices 608 relative to that caused by the illumination of the light-stressed devices 604. In contrast, the OSC's Li(acac) interface stabilizing layer 612 shows improved photo-stability compared to the device without an interface stabilizing layer 616 and the device with the LiF interface stabilizing layer 614. The Li(acac) devices 612 decreased to about 90% of their original PCE 610 values. In contrast, the LiF devices 614 decreased to about 75% of their original PCE 610 values. These results show that the photo-stability of OSCs is limited by photo-induced changes that occur at the active organic layer/Al electrode interface, and that interface stabilizing layers according to embodiments of the present disclosure can improve photo-stability by minimizing photo-induced degradation.

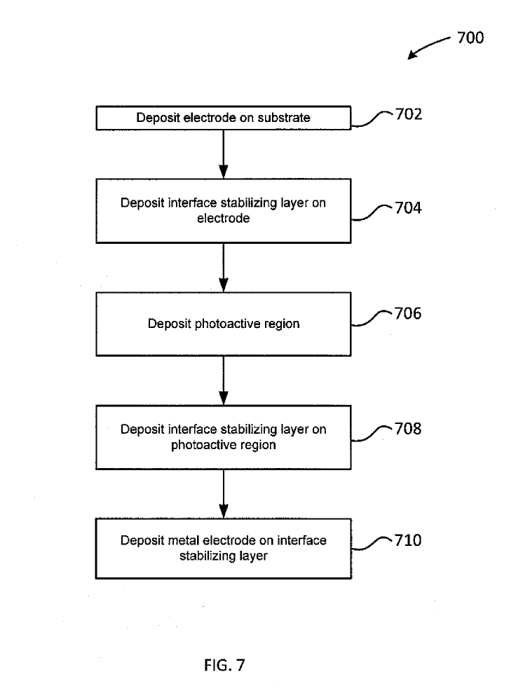

Turning to FIG. 7, a method 700 for manufacturing a photovoltaic device, in accordance with an embodiment of the disclosure is illustrated. Initially, a bottom electrode is deposited on a substrate layer 702. The substrate layer may be a pre-purchased item as these are readily available. In some cases, the electrode and the substrate may be integrated and seen as one component and therefore, there is no need to deposit the bottom electrode. Depending on the structure of the photovoltaic device, or bottom electrode, an interface stabilizing layer may be deposited on the bottom electrode 704 (such as to manufacture the photovoltaic device 200 of FIG. 2 or the photovoltaic device 300 of FIG. 3). A photoactive layer is then deposited 706, for example, by spin-coating or thermal evaporation, ink-jet, or spraying on to the bottom electrode or the interface stabilizing layer. For example, an organic photoactive layer may be deposited via a spin-coating process and subsequently baked on a commercially available ITO-glass substrate.

After the photoactive layer has been deposited, an interface stabilizing layer may be deposited on the photoactive layer 708 (such as to manufacture the photovoltaic device 100 of FIG. 1 or the photovoltaic device 300 of FIG. 3). Depending on the structure of the photovoltaic device, this may or not be necessary. Finally, a top metal electrode is deposited 710, such as vacuum deposited, on the interface stabilizing layer or directly on the photoactive layer, depending on the structure of the photovoltaic device. The assembled photovoltaic device may then be connected to an electricity receiving device.

Deposition of the interface stabilization layer(s) may occur by deposition techniques such as but not limited to solution coating, thermal evaporation, ink-jet deposition, spin coating, sputtering, chemical vapor deposition, spraying, blade coating, web coating, slot coating, and dip coating.

In the preceding description, for purposes of explanation, numerous details are set forth in order to provide a thorough understanding of the embodiments. However, it will be apparent to one skilled in the art that these specific details are not required. In other instances, well-known electrical structures and circuits are shown in block diagram form in order not to obscure the understanding.

The above-described embodiments are intended to be examples only. Alterations, modifications and variations can be effected to the particular embodiments by those of skill in the art without departing from the scope, which is defined solely by the claims appended hereto.

1. A photovoltaic device for converting solar power into electric power, the photovoltaic device comprising:
a first electrode;
a second electrode;
an organic photoactive region in between the first electrode and the second electrode; and
an interface stabilizing region in between the organic photoactive region and one of the first electrode and the second electrode;
wherein the interface stabilizing region is selected from at least one of a non-conjugated organic material, a non-conjugated metalloorganic compound, and a non-alkali metal halide inorganic metal compound.

2. The photovoltaic device of claim 1 wherein the interface stabilizing region comprises a metal acetylacetonate.

3. The photovoltaic device of claim 2 wherein the interface stabilizing region comprises any one of lithium acetylacetonate, barium acetylacetonate, sodium acetylacetonate, calcium acetylacetonate and aluminum acetylacetonate.

4. (canceled)

5. The photovoltaic device of claim 1 wherein the interface stabilizing region comprises a metal carbonate or a metal oxide.

6. The photovoltaic device of claim 1 wherein the first electrode comprises a metal and the interface stabilizing region contacts the first electrode.

7. The photovoltaic device of claim 6 wherein the metal is selected from the group consisting of aluminum (Al), magnesium (Mg), silver (Ag), calcium (Ca), indium (In), barium (Ba), strontium (Sr), gold (Au), molybdenum (Mo), chromium (Cr), and lithium (Li).

8. (canceled)

9. The photovoltaic device of claim 1 wherein the interface stabilizing region has a thickness of 0.1 nm to 10 nm.

10-11. (canceled)

12. The photovoltaic device of claim 1 further comprising:
a second interface stabilizing region between the organic photoactive region and the other of the first electrode and the second electrode;
wherein the second interface stabilizing region is selected from at least one of a non-conjugated organic material, a non-conjugated metalloorganic compound, and a non-alkali metal halide inorganic metal compound.

13. The photovoltaic device of claim 12 wherein the second interface stabilizing region comprises molybdenum trioxide (MoO3).

14. The photovoltaic device of claim 1 further comprising:
a hole extraction layer or an electron extraction layer between the first electrode and the second electrode.

15. A method of manufacturing a photovoltaic device, the method comprising:
obtaining a bottom electrode;
obtaining a top electrode;
depositing an organic photoactive region above the bottom electrode and below the top electrode; and
depositing an interface stabilizing region between the organic photoactive region and one of the bottom electrode and the top electrode;
wherein the interface stabilizing region is selected from at least one of a non-conjugated organic material, a non-conjugated metalloorganic compound, and a non-alkali metal halide inorganic metal compound.

16. The method of claim 15 wherein depositing the interface stabilizing region comprises depositing a metal acetylacetonate.

17. The method of claim 16 wherein depositing the interface stabilizing region comprises depositing any one of lithium acetylacetonate, barium acetylacetonate, sodium acetylacetonate, calcium acetylacetonate and aluminum acetylacetonate.

18. (canceled)

19. The method of claim 15 wherein depositing the interface stabilizing region comprises depositing a metal carbonate or a metal oxide.

20. The method of claim 15 wherein one of the bottom electrode and the top electrode comprises a metal electrode and the interface stabilizing layer is deposited on the metal electrode.

21. The method of claim 20 wherein the metal electrode comprises a metal selected from the group consisting of aluminum (Al), magnesium (Mg), silver (Ag), calcium (Ca), indium (In), barium (Ba), strontium (Sr), gold (Au), molybdenum (Mo), chromium (Cr), and lithium (Li).

22. (canceled)

23. The method of claim 15 wherein depositing the interface stabilizing region comprises depositing a thickness of 0.1 nm to 10 nm.

24-25. (canceled)

26. The method of claim 15 further comprising:
depositing a second interface stabilizing region between the organic photoactive region and the other of the bottom electrode and the top electrode;
wherein the second interface stabilizing region is selected from at least one of a non-conjugated organic material, a non-conjugated metalloorganic compound, and a non-alkali metal halide inorganic metal compound.

27. (canceled)

28. The method of claim 15 further comprising:
depositing a hole extraction layer or an electron extraction layer between the top electrode and the bottom electrode.

29. The photovoltaic device of claim 1 wherein the interface stabilizing region comprises any one or more of a hydrocarbon and an organic compound including fluorine.
